(19) United States
(12) Patent Application Publication
(10) Pub. No.: US 2019/0033340 A1
(43) Pub. Date: Jan. 31, 2019

(54) PIEZOELECTRIC DEVICE

(71) Applicant: Murata Manufacturing Co., Ltd., Nagaokakyo-shi, (JP)

(72) Inventor: Shinsuke Tani, Nagaokakyo-shi (JP)

(21) Appl. No.: 16/057,987

(22) Filed: Aug. 8, 2018

Related U.S. Application Data
(63) Continuation of application No. PCT/JP2017/000421, filed on Jan. 10, 2017.

(30) Foreign Application Priority Data
Feb. 22, 2016 (JP) 2016-030983

(51) Int. Cl. G01P 15/09; H01L 41/047; H01L 41/113; H01L 41/187; G11C 11/22

(52) U.S. Cl. CPC G01P 15/09; H01L 41/047; G11C 11/22; H01L 41/187; H01L 41/113

(57) ABSTRACT

A piezoelectric device that includes a ferroelectric layer having a first surface and a second opposing surface. Moreover, a first electrode is provided that covers part of the first surface and a second electrode is provided that is spaced apart from the first electrode and covers part of the first surface that is not covered by the first electrode. In addition, a third electrode is provided that covers part of the second surface so as to include a region of the second surface that faces the first electrode and a fourth electrode is provided that is spaced apart from the third electrode and covers part of the second surface that is not covered by the third electrode. Moreover, the fourth electrode faces at least part of the second electrode with the ferroelectric layer interposed therebetween. Each electrode can be formed of a sintered material.

### CROSS REFERENCE TO RELATED APPLICATIONS

The present application is a continuation of PCT/JP2017/000421 filed Jan. 10, 2017, which claims priority to Japanese Patent Application No. 2016-030983, filed Feb. 22, 2016, the entire contents of each of which are incorporated herein by reference.

### TECHNICAL FIELD

The present disclosure relates to a piezoelectric device, and, more particularly, to a piezoelectric device configured an impact sensor.

### BACKGROUND

Japanese Unexamined Patent Application Publication No. 2013-96931 (hereinafter “Patent Document 1”) discloses an impact detecting and recording device that can detect and record an impact acting thereon without having a source of power. In Patent Document 1, in order to obtain this device, an impact sensor and a ferroelectric memory are separately manufactured, and then the impact sensor and the ferroelectric memory are integrated with each other by bonding electrodes of the impact sensor and the ferroelectric memory to each other using a conductive adhesive. An impact sensor is typically manufactured by forming electrodes on a piezoelectric ceramic plate, which is molded to have a desired thickness, and so forth. On the other hand, a ferroelectric memory is manufactured by depositing and patterning films on a Si wafer by using thin film processes, and so forth.

Therefore, when actually manufacturing the device disclosed in Patent Document 1, it is necessary to carry out an impact sensor manufacturing process mainly consisting of processing a sintered piezoelectric ceramic plate, a ferroelectric memory manufacturing process mainly consisting of thin film processes, and an integration process in which the impact sensor and the ferroelectric memory are electrically and mechanically bonded to each other.

Japanese Unexamined Patent Application Publication No. 2007-329393 (hereinafter “Patent Document 2”) discloses a semiconductor device in which a sensor and a ferroelectric memory are both provided.
Patent Document 1: Japanese Unexamined Patent Application Publication No. 2013-96931.
Patent Document 2: Japanese Unexamined Patent Application Publication No. 2007-329393.
Patent Document 3: International Publication No.

2015/166914.

Since the piezoelectric body used in the impact sensor disclosed in Patent Document 1 is also a ferroelectric body, if a ferroelectric memory were manufactured that utilizes polarization inversion of this piezoelectric body, it would be possible to significantly shorten the above-described processes. However, the thickness of the piezoelectric body used in the impact sensor is greater than or equal to 100 μm, and it is estimated that a voltage greater than or equal to 100 V would be required to invert the polarization of a piezoelectric body of this thickness. If the electrode generated between the two ends of the ferroelectric memory were 100 V or, more specifically, a high voltage of over 40 V, it would be necessary to ensure that the surrounding circuits were capable of withstanding such a high voltage, and a great deal of effort would be required at the design stage with respect to reliability. On the other hand, if an attempt were made to process the piezoelectric body used in the impact sensor so that the piezoelectric body became thin enough that the polarization could be inverted with a voltage of around 10 V, the thickness of the piezoelectric body would have to be less than or equal to 20 In such a case, it would be highly likely that the piezoelectric body itself would be damaged during the manufacturing an element that includes processing for reducing the thickness of the piezoelectric body, and the element would not be able to withstand being handled in reality.

As described above, when an attempt is made to use the same body as the piezoelectric body used in the impact sensor and the ferroelectric body used in the ferroelectric memory in order to simplify the manufacturing process, the design process in terms of reliability and the manufacturing process become difficult and implementation has not been possible.

Since the piezoelectric sensor and the ferroelectric memory are both manufactured using thin film processes in Patent Document 2, resolving the complexity of the manufacturing process that is a concern in Patent Document 1 is anticipated. On the other hand, in order to manufacture a piezoelectric sensor that generates sufficient charge to invert the polarization of a ferroelectric memory, there are restrictive conditions relating to the dimensions of the piezoelectric body, and a great deal of effort is required to manufacture a piezoelectric sensor that satisfies these conditions using thin film processes.

### SUMMARY OF THE INVENTION

Accordingly, an object of the present disclosure is to provide a piezoelectric device that includes a ferroelectric memory in which the polarization can be inverted using a low voltage, that has a thickness that makes handling thereof possible, and that can be easily manufactured.

Accordingly, a piezoelectric device of a first exemplary aspect of the present disclosure is provided that includes a ferroelectric layer having a first surface and a second surface that face in opposite directions; a first electrode that covers part of the first surface and is formed of a sintered metal; and a second electrode that is spaced apart from the first electrode, covers part of a region of the first surface that is not covered by the first electrode, and is formed of a sintered metal. Moreover, the piezoelectric device includes a third electrode that covers part of the second surface so as to include a region of the second surface that faces the first electrode, and that is formed of a sintered metal; and a fourth electrode that is spaced apart from the third electrode, covers part of a region of the second surface that is not covered by the third electrode, and is formed of a sintered metal. In the exemplary aspect, the fourth electrode faces at least part of the second electrode with the ferroelectric layer interposed therebetween.

In the above-described exemplary aspect, the ferroelectric layer preferably has a thickness of 1 to 100 μm.

In the above-described exemplary aspect, the first electrode preferably has a circular shape, and the second electrode is preferably arranged so as to surround the first electrode.

In another exemplary aspect of the above-described piezoelectric device, the first electrode and the second electrode are preferably electrically connected to each other via a diode.

In another exemplary aspect of the above-described piezoelectric device, a first pad electrode is preferably electrically connected to the third electrode, a second pad electrode is preferably electrically connected to the fourth electrode, and the first pad electrode and the second pad electrode can be preferably switched between being electrically connected to each other and not electrically connected to each other.

In the above-described exemplary aspect, the piezoelectric device preferably further includes an insulating film that covers at least part of the first electrode and at least part of the second electrode.

Moreover, a piezoelectric device of a second exemplary aspect of the present disclosure is provided that, when n is an integer greater than or equal to 2, includes a ferroelectric layer having a first surface and a second surface that face in opposite directions; the piezoelectric device further including for each integer k from 1 to n, a kth first electrode formed of a sintered metal on the first surface; a kth second electrode formed of a sintered metal on the first surface; a kth third electrode formed of a sintered metal on the second surface; and a kth fourth electrode formed of a sintered metal on the second surface. Moreover, the kth third electrode includes a region that faces the kth first electrode with the ferroelectric layer interposed therebetween, the kth fourth electrode includes a region that faces at least part of the kth second electrode with the ferroelectric layer interposed therebetween, the first first electrode, the second first electrode, the third first electrode, . . . , the nth first electrode, the first second electrode, the second second electrode, the third second electrode, . . . , and the nth second electrode are spaced apart from each other and arranged in different regions from each other, the first third electrode, the second third electrode, the third third electrode, . . . , the nth third electrode, the first fourth electrode, the second fourth electrode, the third fourth electrode, . . . , and the nth fourth electrode are spaced apart from each other and arranged in different regions from each other, and for 2 different integers k1 and k2 arbitrarily selected from among the integers 1 to n, the k1-th first electrode and the k2-th first electrode have different surface areas from each other.

In the above-described exemplary aspect, the ferroelectric layer preferably has a thickness of 1 to 100 μm.

In the above-described exemplary aspect, for each integer k from 1 to n, the kth first electrode preferably has a circular shape, and the kth second electrode is preferably arranged so as to surround the kth first electrode.

In the above-described exemplary aspect, for each integer k from 1 to n, the kth first electrode and the kth second electrode are preferably electrically connected to each other via a diode.

According to the present disclosure, a memory part and a sensor part are formed by different parts of one ferroelectric layer 1, and therefore it is possible to realize a piezoelectric device for which it is not necessary to separately prepare a memory and a sensor when assembling the piezoelectric device, that includes a ferroelectric memory in which the polarization can be inverted using a low voltage, that has a thickness that makes handling thereof possible, and that can be easily manufactured.

### BRIEF DESCRIPTION OF DRAWINGS

FIG. 1 is a perspective view of a piezoelectric device of exemplary embodiment 1 of the present disclosure.

FIG. 2 is a sectional view looking in the direction of arrows and taken along line II-II in FIG. 1.

FIG. 3 is a perspective view of a state obtained by removing an insulating film and so forth from the piezoelectric device of exemplary embodiment 1 of the present disclosure.

FIG. 4 is a perspective view of a piezoelectric ceramic sheet that is prepared in order to manufacture the piezoelectric device of exemplary embodiment 1 of the present disclosure.

FIG. 5 is a perspective view of a first conductive sheet that is prepared in order to manufacture the piezoelectric device of exemplary embodiment 1 of the present disclosure.

FIG. 6 is a perspective view of a second conductive sheet that is prepared in order to manufacture the piezoelectric device of exemplary embodiment 1 of the present disclosure.

FIG. 7 is a perspective view of a multilayer body that is prepared in order to manufacture the piezoelectric device of exemplary embodiment 1 of the present disclosure.

FIG. 8 is a perspective view of a co-sintered compact obtained during manufacture of the piezoelectric device of exemplary embodiment 1 of the present disclosure.

FIG. 9 is a sectional view of the co-sintered compact obtained during manufacture of the piezoelectric device of exemplary embodiment 1 of the present disclosure.

FIG. 10 is a perspective view of a first state that occurs during manufacture of the piezoelectric device of exemplary embodiment 1 of the present disclosure.

FIG. 11 is a sectional view corresponding to FIG. 10.

FIG. 12 is a perspective view of a second state that occurs during manufacture of the piezoelectric device of exemplary embodiment 1 of the present disclosure.

FIG. 13 is a sectional view corresponding to FIG. 12.

FIG. 14 is a perspective view of a third state that occurs during manufacture of the piezoelectric device of exemplary embodiment 1 of the present disclosure.

FIG. 15 is a sectional view corresponding to FIG. 14.

FIG. 16 is a perspective view of a fourth state that occurs during manufacture of the piezoelectric device of exemplary embodiment 1 of the present disclosure.

FIG. 17 is a sectional view corresponding to FIG. 16.

FIG. 18 is a perspective view of a piezoelectric device of exemplary embodiment 2 of the present disclosure.

FIG. 19 is a sectional view of the piezoelectric device of exemplary embodiment 2 of the present disclosure.

FIG. 20 is a perspective view of a piezoelectric device of exemplary embodiment 3 of the present disclosure.

FIG. 21 is a sectional view of the piezoelectric device of exemplary embodiment 3 of the present disclosure.

FIG. 22 is a circuit diagram representing the piezoelectric device of exemplary embodiment 3 of the present disclosure.

FIG. 23 is a graph illustrating hysteresis loops for before and after application of an impact in the case where a large potential difference is generated between a second electrode and a fourth electrode in the piezoelectric device of exemplary embodiment 3 of the present disclosure.

FIG. 24 is a graph illustrating hysteresis loops for before and after application of an impact in a case where a small potential difference is generated between the second electrode and the fourth electrode in the piezoelectric device of exemplary embodiment 3 of the present disclosure.

FIG. 25 is a perspective view of a piezoelectric device of exemplary embodiment 4 of the present disclosure.

FIG. 26 is a plan view of a state obtained by removing an insulating film and so forth from the piezoelectric device of exemplary embodiment 4 of the present disclosure.

FIG. 27 is a bottom view of the piezoelectric device of exemplary embodiment 4 of the present disclosure.

FIG. 28 is a perspective view of a piezoelectric device of exemplary embodiment 5 of the present disclosure.

FIG. 29 is a perspective view of a state obtained by removing an insulating film and so forth from the piezoelectric device of exemplary embodiment 5 of the present disclosure.

### DETAILED DESCRIPTION OF EXEMPLARY EMBODIMENTS

The dimensional ratios depicted in the drawings do not necessarily accurately depict the actual dimensional ratios, and the dimensional ratios in the drawings may be depicted in an exaggerated manner for convenience of explanation. In the following description, when reference is made to the concepts of above and below, the meanings of such terms are not limited to meaning absolutely above and below, but rather mean relatively above and below within the illustrated states.

### Embodiment 1

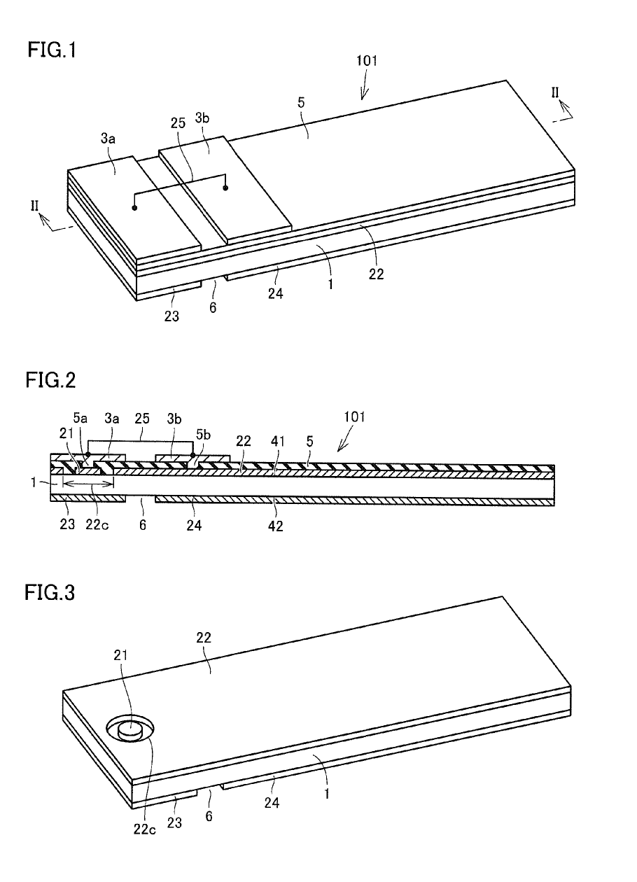

A piezoelectric device of exemplary embodiment 1 of the present disclosure will be described while referring to FIGS. 1 to 3. FIG. 1 is a perspective view of a piezoelectric device 101 of this embodiment. FIG. 2 is a sectional view looking in the direction of the arrows and taken along line II-II in FIG. 1.

As shown, the exemplary piezoelectric device 101 includes a ferroelectric layer 1 having a first surface 41 and a second surface 42 that face in opposite directions; a first electrode 21 that covers part of the first surface 41 and is formed of a sintered metal; a second electrode 22 that is spaced apart from the first electrode 21, covers part of a region of the first surface 41 that is not covered by the first electrode 21, and is formed of a sintered metal; a third electrode 23 that covers part of the second surface 42 so as to include a region of the second surface 42 that faces the first electrode 21, and that is formed of a sintered metal; and a fourth electrode 24 that is spaced apart from the third electrode 23, covers part of a region of the second surface 42 that is not covered by the third electrode 23, and is formed of a sintered metal. Moreover, in this aspect, the fourth electrode 24 faces at least part of the second electrode 22 (i.e., the electrodes overlap each other) with the ferroelectric layer 1 interposed therebetween.

In addition, the piezoelectric device 101 includes an insulating film 5 that covers the first electrode 21 and the second electrode 22. As shown, the piezoelectric device 101 further includes extension electrodes 3a and 3b that each cover part of the insulating film 5. The extension electrodes 3a and 3b are provided so as to be spaced apart from each other, but are electrically connected to each other via a wiring line 25. FIG. 3 illustrates a state obtained by removing the extension electrodes 3a and 3b, the wiring line 25, and the insulating film 5 from FIG. 1. The second electrode 22 has an opening 22c. The first electrode 21 is arranged inside the opening 22c. The first electrode 21 has a circular shape and is arranged in a concentric circular manner with respect to the opening 22c. The first electrode 21 is spaced apart from the second electrode 22. The fourth electrode 24 is spaced apart from the third electrode 23 with a gap 6 interposed therebetween. The first electrode 21 is not limited to having a circular shape, and may instead have an elliptical shape or a polygonal shape, for example.

In one exemplary aspect, the ferroelectric layer 1 can be formed using the technique described in International Publication No. 2015/166914 (Patent Document 3 as identified above), for example. With this technique, a ferroelectric layer 1 having a thickness of 100 μm or less can be manufactured. The ferroelectric layer 1 can be obtained by performing firing.

The first electrode 21, the second electrode 22, the third electrode 23, and the fourth electrode 24 can also be obtained by performing firing. In an exemplary aspect, the ferroelectric layer 1, the first electrode 21, the second electrode 22, the third electrode 23, and the fourth electrode 24 can be simultaneously manufactured as sintered bodies by stacking the materials of these components on top of one another and firing the materials in this state in one go.

Moreover, the piezoelectric device 101 of the exemplary embodiment has a structure in which the same ferroelectric layer 1 is used as both a ferroelectric memory and an impact sensor. The part of the one ferroelectric layer 1 that is inside a projected region of the first electrode 21 serves as a ferroelectric memory. For purposes of this disclosure, this part is referred to as “memory part” hereafter. On the other hand, the part of the ferroelectric layer 1 that is in the region interposed between the second electrode 22 and the fourth electrode 24 serves as an impact sensor. For purposes of this disclosure, this part is referred to as a “sensor part” hereafter. In this exemplary embodiment, since the memory part and the sensor part are formed of different parts of this one ferroelectric layer 1, there is no need to individually prepare the memory and the sensor when assembling the piezoelectric device. Therefore, the piezoelectric device of this embodiment can be manufactured without going through a process for electrically and mechanically connecting the memory part and the sensor part to each other. Moreover, the fact that there is no need for such a connection process means that problems relating to the reliability of a connection portion can also be avoided. Since both the memory part and the sensor part can be realized using a thin sintered body, a reduction in the thickness of the piezoelectric device can advantageously be achieved compared with the conventional designs disclosed in Patent Document 1. According to the exemplary embodiment, a piezoelectric device is provide that includes a ferroelectric memory in which the polarization can be inverted using a low voltage, that has a thickness that makes handling thereof possible, that can be easily manufactured, and that can be used as an impact sensor.

Moreover, in the piezoelectric device 101 of this embodiment, part of the ferroelectric layer 1 serves as a sensor part and information can be written into the memory part using charge that is generated in the sensor part when an impact occurs, and therefore the piezoelectric device 101 can detect and record an impact by itself without the need for power supplied from the outside.

To realize the same configuration as this embodiment in Patent Document 2, it would be necessary to repeatedly perform a coating step, a drying step, and a degreasing thermal treatment step, whereas in this embodiment, a ferroelectric body of a desired thickness can be manufactured by preparing sheets having a thickness of around 1 μm, and then stacking and firing the sheets, and therefore the manufacturing method can be greatly simplified.

In the description of this embodiment, it is assumed that the impact sensor has a unimorph structure, but the present disclosure is not limited to a unimorph structure. Provided that the total thickness of the piezoelectric device is 100 μm or less, a multimorph structure may be adopted.

In addition, it is preferable that the thickness of the ferroelectric layer 1 be from 1 to 100 By providing this configuration, a ferroelectric layer 1 that serves as both a ferroelectric memory and an impact sensor can be manufactured by performing firing using the above-described method.

According to the exemplary embodiment, it is preferable that the first electrode 21 have a circular shape and that the second electrode 22 be arranged so as to surround the first electrode 21. Advantageously, this configuration provides that the surface area of the first electrode 21 can be unambiguously determined using the diameter. In addition, as a result of adopting this configuration, the region of the ferroelectric layer 1 that is not covered by either the first electrode 21 or the second electrode 22 can be made small. The ferroelectric layer 1 being covered by either electrode simply means that a ceramic having brittleness is covered by a metal having malleability and the mechanical strength of the ferroelectric layer 1 is reinforced in that region, and if the second electrode 22 is arranged so as to surround the first electrode 21, the region that is reinforced in this way can be made large, and therefore generated stress can be relaxed, and the risk of the ferroelectric layer 1 breaking during processing of the electrodes can be reduced.

Yet further, the insulating film 5 is preferably provided to cover at least part of each of the first electrode 21 and the second electrode 22. As a result of adopting this configuration, at least part of each of the first electrode 21 and the second electrode 22 is covered by the insulating film 5, and therefore the probability of the occurrence of unwanted short circuits can be reduced.

(Manufacturing Method)

An exemplary method for manufacturing the piezoelectric device of this embodiment will be described.

First, ceramic element raw materials are prepared. For example, in the case where a piezoelectric ceramic substrate that will become the ferroelectric layer 1 is formed of an alkali-niobate-based compound, a K compound, a Na compound, a Li compound, a Nb compound, or the like is prepared. Alternatively, in the case where the piezoelectric ceramic substrate that will become the ferroelectric layer 1 is formed of a PZT-based compound, a Pb compound, a Ti compound, a Zr compound, or the like is prepared, and various additives are prepared as necessary.

Next, the ceramic element raw materials are weighed so as to realize a prescribed composition molar ratio. The weighed materials are put into a pot mill inside of which a grinding medium such as PSZ balls is arranged. The pot mill is rotated with the presence of a solvent for a prescribed period of time. As a result, the ceramic element raw materials are sufficiently mixed and crushed in a wet process. In addition, the crushed material is dried, and then a ceramic raw material powder is obtained by performing a calcining treatment.

The ceramic raw material powder is crushed and is then put in the pot mill once again together with an organic binder, an organic solvent, a dispersant, a plasticizer, and the previously mentioned grinding medium, and a ceramic slurry is obtained by sufficiently mixing and crushing the material in a wet process while rotating the pot mill.

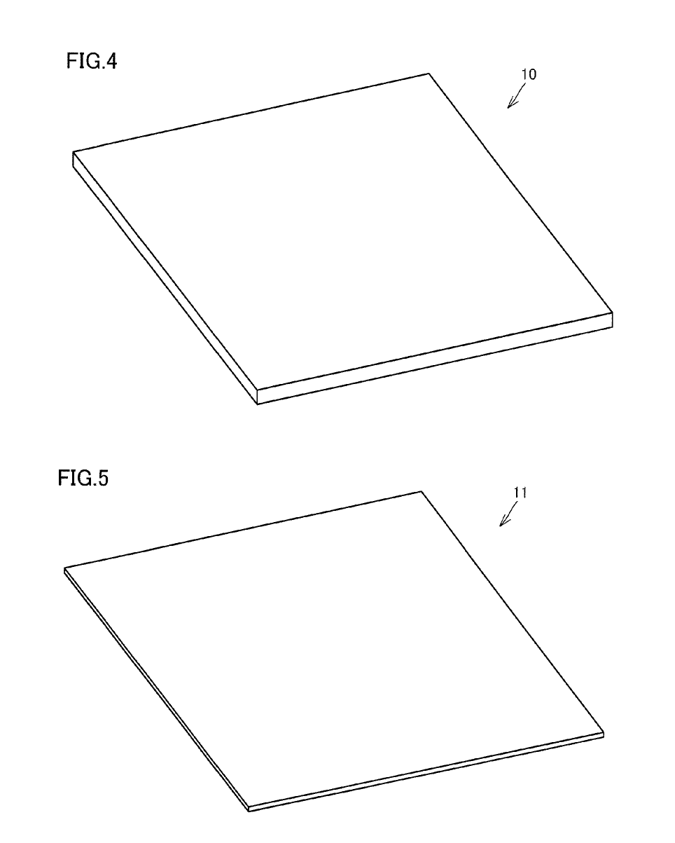

The ceramic slurry is molded using a doctor blade method, and a piezoelectric ceramic sheet is manufactured such that the thickness of the sheet after firing is preferably 100 μm or less. A piezoelectric ceramic sheet 10 is illustrated in FIG. 4. In this case, although the piezoelectric ceramic sheet 10 is illustrated as having a square shape as an example, the shape of the piezoelectric ceramic sheet 10 is not limited to this example.

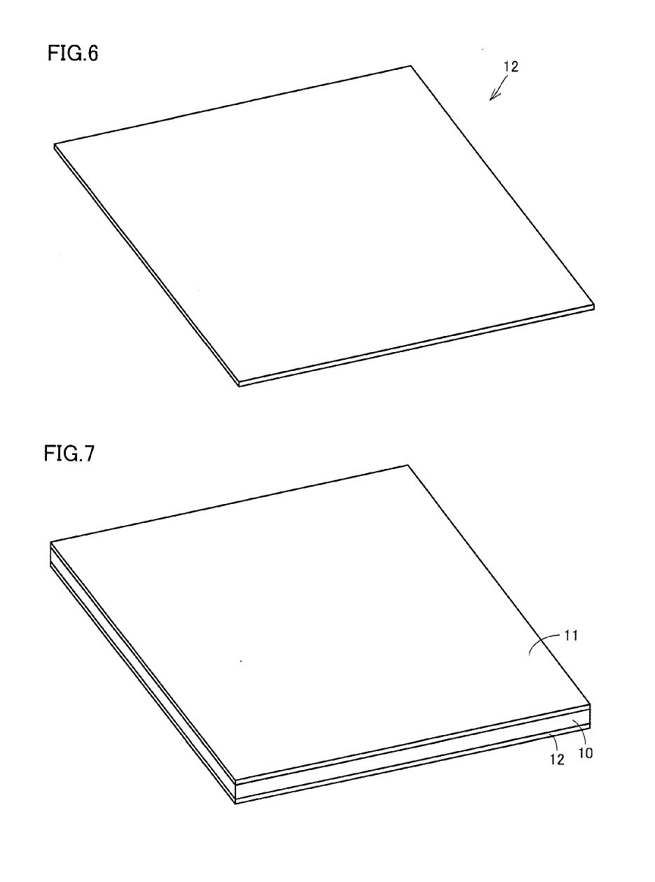

Similarly, a conductive material such as Ni or Cu is prepared. This conductive material is put into a pot mill, inside of which a grinding medium is arranged, together with an organic binder, an organic solvent, a dispersant, and a plasticizer, and the materials are sufficiently wet mixed in a wet process while rotating the pot mill. As a result, a conductive slurry is manufactured. Next, the conductive slurry is molded using a doctor blade method, and two conductive sheets are manufactured such that the thicknesses of the sheets after firing are preferably 1 to 40 μm, as illustrated in FIGS. 5 and 6. A first conductive sheet 11 is illustrated in FIG. 5. A second conductive sheet 12 is illustrated in FIG. 6.

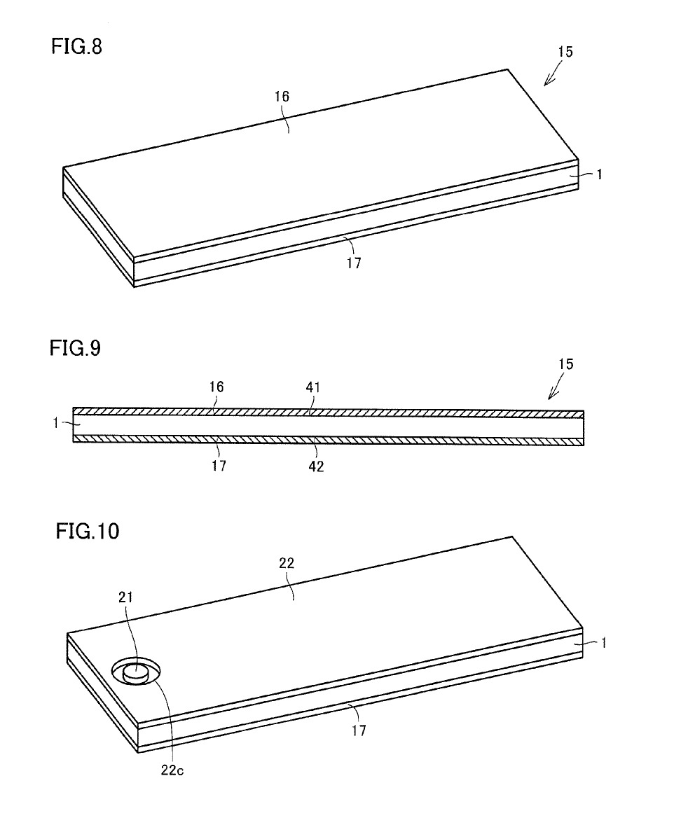

As illustrated in FIG. 7, the piezoelectric ceramic sheet 10 is sandwiched between the first conductive sheet 11 and the second conductive sheet 12, and a multilayer body in which 3 layers are stacked on top of one another is thus obtained. The multilayer body is fired. The fired multilayer body is cut into a desired shape. A co-sintered compact 15 is thus obtained as illustrated in FIGS. 8 and 9. The co-sintered compact 15 is manufactured so as to have a rectangular shape of 40 mm×10 mm in a plan view, for example. FIG. 9 is a sectional view of the co-sintered compact 15 illustrated in FIG. 8. A first conductor layer 16 is formed on the first surface 41 of the ferroelectric body 1 and a second conductor layer 17 is formed on the second surface 42 of the ferroelectric body 1 in the co-sintered compact 15.

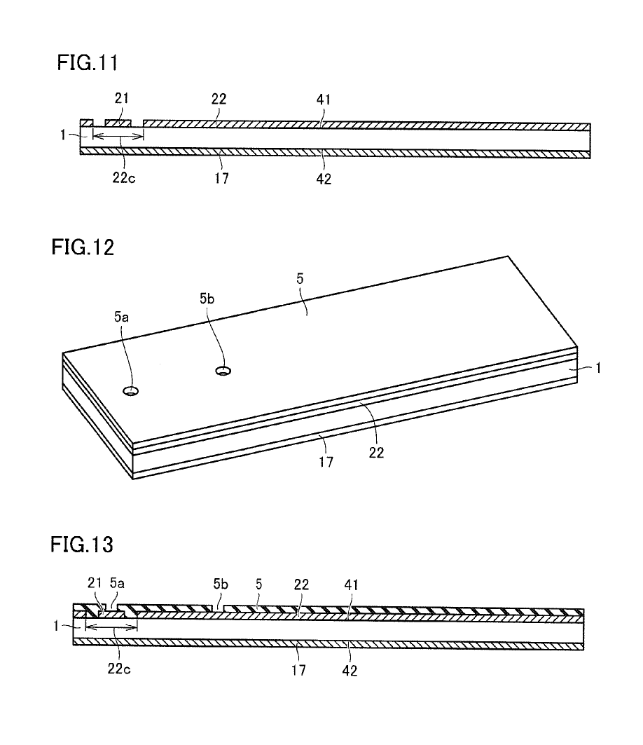

Next, the first conductor layer 16 is patterned using a photolithography technique. In the patterning processing, a photoresist is applied to the surface of the first conductor layer 16, pre-baking is performed, and then a mask having a prescribed pattern is arranged thereon and the mask pattern is transferred to the photoresist by exposing the pattern to ultraviolet light. Next, the pattern is developed, and then washing is performed with pure water. After that, the body is immersed in an etching liquid such as a ferric chloride solution and wet etching is performed. The developed photoresist is peeled off using a peeling solution. As a result of performing this patterning processing, the first conductor layer 16 is divided into two pieces, and as illustrated in FIG. 10, the first electrode 21 and the second electrode 22 are formed. FIG. 11 illustrates a sectional view of this state.

Next, the insulating film 5 is formed so as to cover the first electrode 21 and the second electrode 22. A part where the ferroelectric layer 1 is exposed inside the opening 22c of the second electrode 22 is also covered by the insulating film 5. However, openings 5a and 5b are formed in the insulating film 5 such that part of the first electrode 21 and part of the second electrode 22 are exposed therethrough, as illustrated in FIG. 12. FIG. 13 illustrates a sectional view of this state.

In order to form the insulating film 5, for example, an insulating solution that contains a photosensitive insulating material such as a photosensitive epoxy resin is prepared. The insulating solution is applied using a coating method such as a spin coating method. After that, prebaking is performed, light exposure through a mask having a prescribed pattern is performed, and the pattern is developed. In addition, post-baking is performed, and the insulating film 5 having the openings 5a and 5b can be thus obtained.

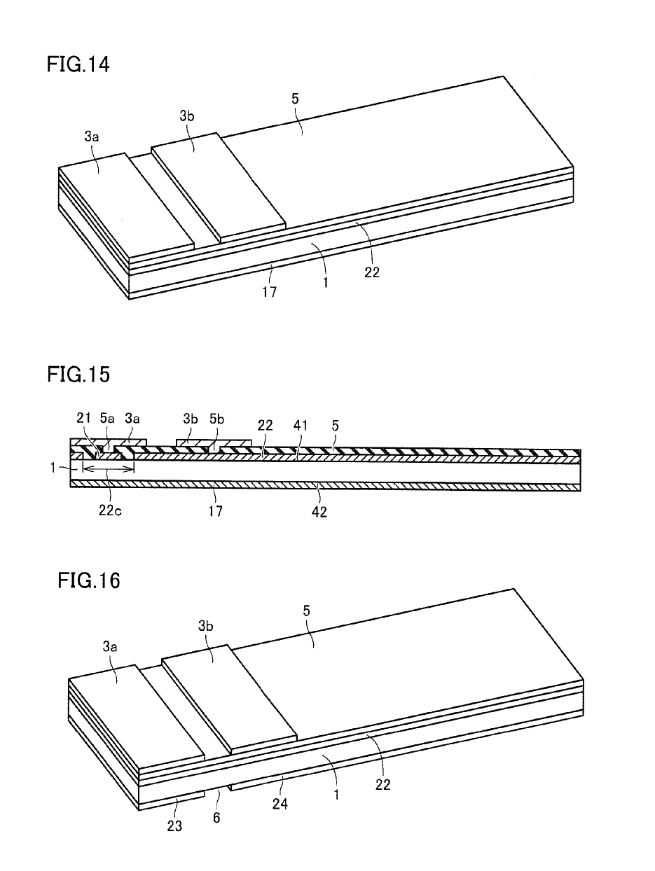

Next, the extension electrodes 3a and 3b are formed. That is, first, a conductive layer is formed on the surface of the multilayer body on which the insulating film 5 has been formed by using a thin film forming method such as a sputtering method. After that, the extension electrodes 3a and 3b are formed in the conductive layer, as illustrated in FIG. 14, by using the above-mentioned photolithography technique. FIG. 15 illustrates a sectional view of this state.

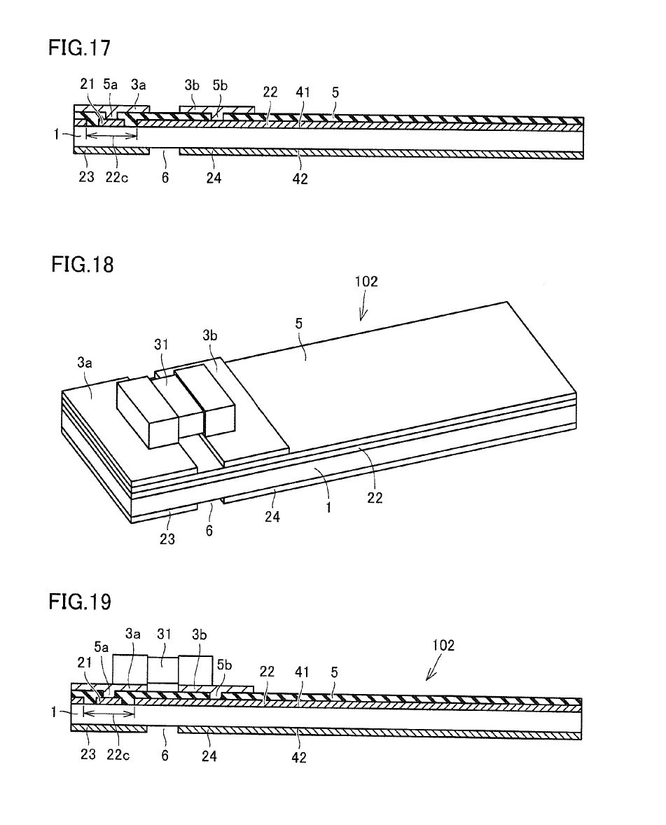

Next, the second conductor layer 17 is patterned using a photolithography technique. As a result, the second conductor layer 17 is divided into two pieces. Thus, as illustrated in FIGS. 16 and 17, the third electrode 23 and the fourth electrode 24 are formed.

Next, the extension electrodes 3a and 3b are electrically connected to each other using an appropriate method. If a signal generated by the sensor part is to be applied to the memory part as it is in the form of an alternating current, a resistor chip having a low resistance may be mounted so as to span between the extension electrodes 3a and 3b so as to realize a connection therebetween. Thus, the piezoelectric device 101 illustrated in FIGS. 1 and 2 can be obtained. Here, the way in which the extension electrodes 3a and 3b are connected to each other is schematically represented as the wiring line 25.

In one exemplary aspect, when the signal is applied to the memory part as it is in the form of an alternating current, instead of connecting the extension electrodes 3a and 3b to each other using the wiring line 25, the extension electrodes 3a and 3b may be formed as connected integrated electrodes rather as individual electrodes when manufacturing the extension electrodes 3a and 3b.

According to the exemplary aspect, the various electrode processing steps, in which a photolithography technique is used, are performed after the fired multilayer body is cut into a desired shape. However, alternatively, it is noted that the steps from the electrode processing up to connecting the electrodes to each other may be performed with the fired multilayer body as it is in a large piece without having been cut yet, and after that the multilayer body may then be cut into the desired shape. In this case, a reduction in manufacturing cost can be achieved.

### Embodiment 2

A piezoelectric device according to exemplary embodiment 2 of the present disclosure will be described while referring to FIGS. 18 and 19. A piezoelectric device 102 of this embodiment is illustrated in FIG. 18. FIG. 19 is a sectional view of the piezoelectric device 102.

As noted above, the extension electrodes 3a and 3b are connected to each other by the wiring line 25 in the piezoelectric device 101 described in exemplary embodiment 1, whereas in the piezoelectric device 102 of this exemplary embodiment 2, the extension electrodes 3a and 3b are connected to each other by a diode 31. The diode 31 is a chip-shaped component. In the piezoelectric device 102, the first electrode 21 and the second electrode 22 are electrically connected to each other via the diode 31.

In this embodiment, since the first electrode 21 and the second electrode 22 are connected to each other via the diode 31, the alternating current signal generated by the sensor part is rectified by the diode 31 and then applied to the memory part.

### Embodiment 3

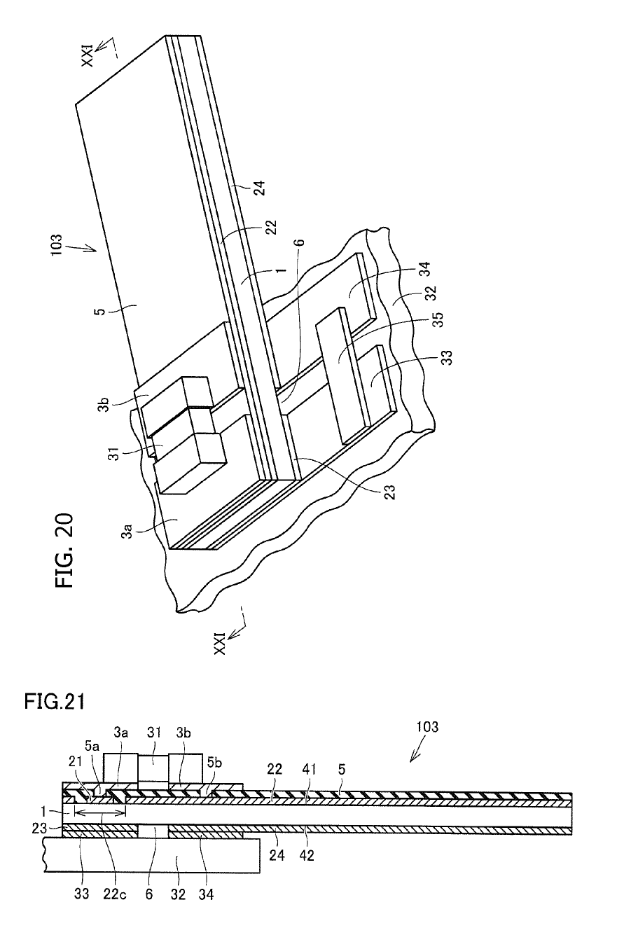

A piezoelectric device according to exemplary embodiment 3 of the present disclosure will be described while referring to FIGS. 20 to 22. A piezoelectric device 103 of this embodiment is illustrated in FIG. 20. FIG. 21 is a sectional view looking in the direction of the arrows and taken along line XXI-XXI in FIG. 20. The piezoelectric device 103 includes a substrate 32. A first pad electrode 33 and a second pad electrode 34 are arranged on a surface of the substrate 32. In the piezoelectric device 103, the first pad electrode 33 is electrically connected to the third electrode 23, the second pad electrode 34 is electrically connected to the fourth electrode 24, and the first pad electrode 33 and the second pad electrode 34 can be switched between being electrically connected to each other and not electrically connected to each other.

As illustrated in FIG. 20, a switch 35 is arranged between the first pad electrode 33 and the second pad electrode 34. The first pad electrode 33 and the second pad electrode 34 can be switched between being electrically connected to each other and not electrically connected to each other by operating the switch 35. Moreover, a part of the piezoelectric device 103 that extends from the substrate 32 like a cantilever beam produces a vibration when an impact acts on the entire piezoelectric device 103. The vibration generated in this part is converted into an electrical signal by the sensor part of the ferroelectric layer 1. This electrical signal is rectified by the diode 31, a potential difference is generated between the first electrode 21 and the third electrode 23, and the rectified electrical signal is input to the memory part of the ferroelectric layer 1.

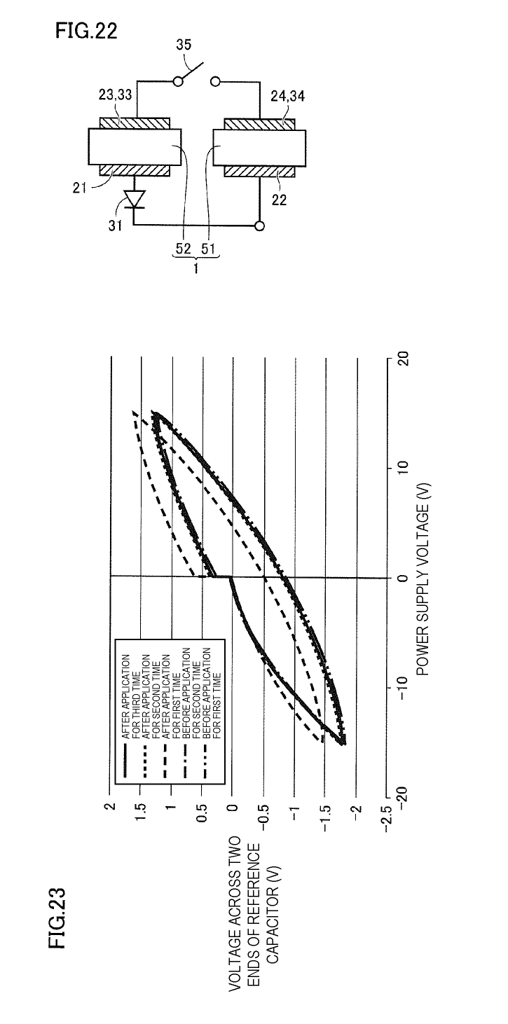

FIG. 22 is circuit diagram of the piezoelectric device 103 of this embodiment. The piezoelectric device 103 includes a sensor part 51 and a memory part 52.

In an experimental example, the piezoelectric device 103 was manufactured such that the thickness of the piezoelectric film was 15 μm, and the thicknesses of the first conductor layer 16 and the second conductor layer 17 were around 2 In this instant, a constant voltage was applied between the second electrode 22 and the second pad electrode 34 of the piezoelectric device 103, and the region of the ferroelectric layer 1 corresponding to the sensor part was polarized. After that, in a state where the switch 35 is switched ON, an impact was artificially applied by hitting the impact sensor part with the shaft part of a pair of tweezers. A potential difference was generated between the first electrode 21 and the third electrode 23 by this impact. Impacts of several different sizes were applied, and as a result, potential differences on the order of 1-20 V were detected in accordance with the size of the applied impacts.

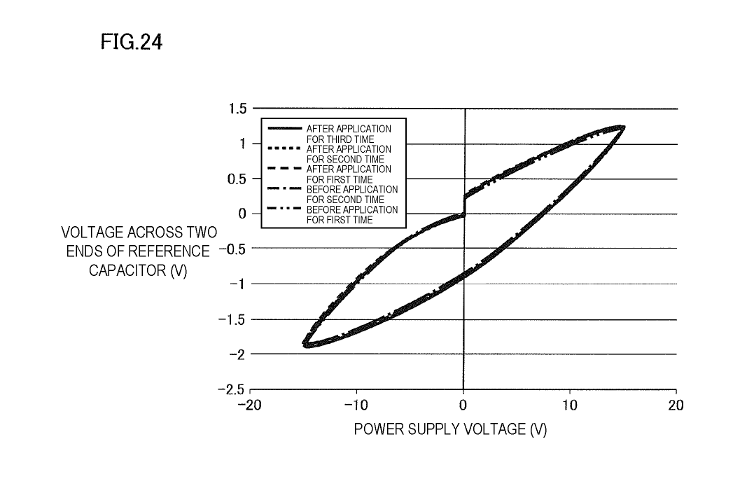

In another experimental example, the piezoelectric device 103 was connected to a Sawyer-Tower circuit in a state where the switch 35 was turned OFF, and hysteresis loops were measured between the first electrode 21 and the third electrode 23. When an electrical signal generated when an impact was applied was rectified in a negative direction by the diode 31 and positive and negative voltages were defined, sweeping of the voltage was performed when measuring hysteresis in the order of 0→negative→positive→0. As a result, in the case where the potential difference generated between the second electrode 22 and the fourth electrode 24 was large when an impact was applied, as illustrated in FIG. 23, there was a large difference between the shapes of the hysteresis loops before and after application of the impact, whereas in the case where the potential difference generated between the second electrode 22 and the fourth electrode 24 was small when an impact was applied, as illustrated in FIG. 24, no difference could be seen between the shapes of the hysteresis loops before and after application of the impact.

From this experiment, it could be confirmed that a large potential difference can be generated by applying a strong impact to the sensor part and the polarization state of the memory part can be changed via this potential difference.

Here, a case in which the sensor part has a unimorph structure has been described as an example, but the present disclosure is not necessarily limited to a unimorph structure. Provided that the total thickness of the ferroelectric layer 1 is 100 μm or less, a multimorph structure may be adopted.

### Embodiment 4

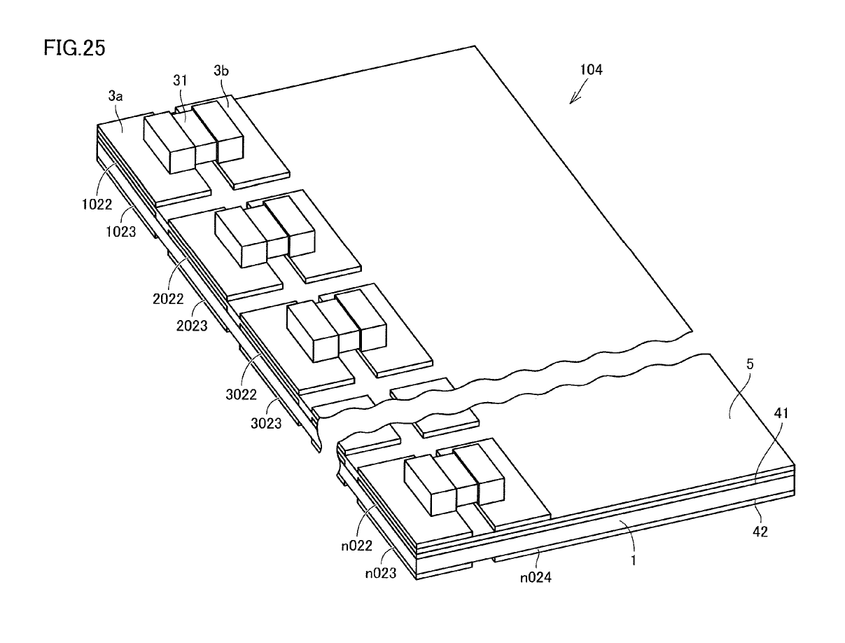

A piezoelectric device according to exemplary embodiment 4 of the present disclosure will be described while referring to FIGS. 25 to 27. A piezoelectric device 104 of this embodiment is illustrated in FIG. 25. The piezoelectric device 104 includes a plurality of memory parts. In the example illustrated in FIG. 25, the piezoelectric device 104 includes first to nth, i.e., a total of n, memory parts. In this aspect, the piezoelectric device 104 includes n sensor parts corresponding to the n memory parts. Together, each of the n memory parts and n sensor parts can collectively be considered an n “memory and sensor component” for purposes of this disclosure. In the piezoelectric device 104, a single ferroelectric layer 1 may be commonly used by the n memory parts and the n sensor parts. Regarding the insulating film 5 as well, similarly, a single film may be formed in a continuous manner.

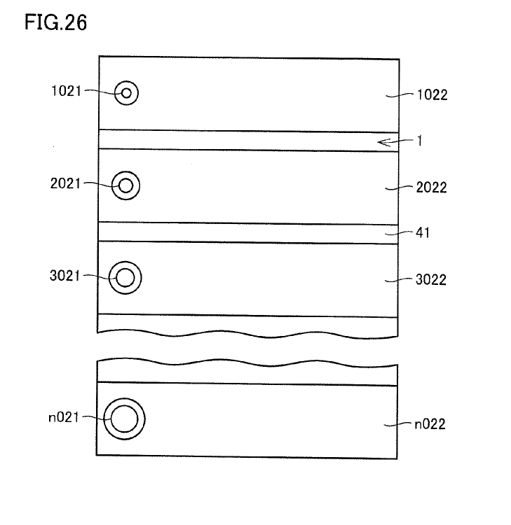

FIG. 26 illustrates from above the state in FIG. 25 in which the insulating film 5 and so on have been removed from the piezoelectric device 104. In FIG. 26, the state is seen from the first surface 41 side of the ferroelectric layer 1. As illustrated in FIG. 26, a first first electrode 1021, a first second electrode 1022, a second first electrode 2021, a second second electrode 2022, a third first electrode 3021, a third second electrode 3022, . . . , an nth first electrode n021, and an nth second electrode n022 are arranged so as to be spaced apart from each other on the first surface 41 of the ferroelectric layer 1. The first first electrode 1021 is formed in an island shape surrounded by the first second electrode 1022. The second first electrode 2021 is formed in an island shape surrounded by the second second electrode 2022. Similarly thereafter, the nth first electrode n021 is formed in an island shape surrounded by the nth second electrode n022. The first first electrode 1021, the second first electrode 2021, the third first electrode 3021, . . . , and the nth first electrode n021 each have a circular shape, and have different diameters from one another. Considering any two electrodes from among the first first electrode 1021, the second first electrode 2021, the third first electrode 3021, . . . , and the nth first electrode n021, the two electrodes will always have different areas.

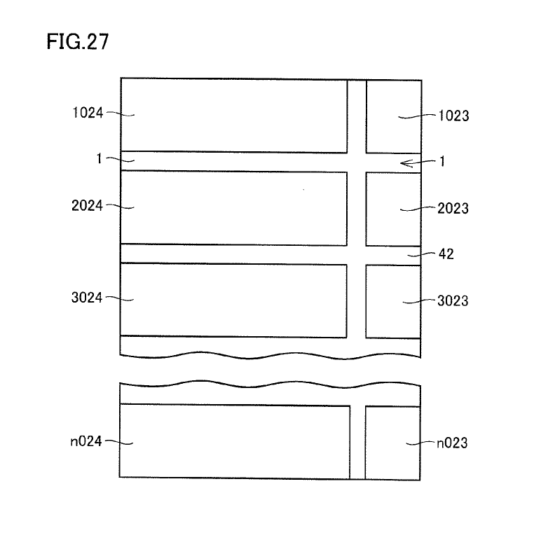

FIG. 27 illustrates the piezoelectric device 104 in FIG. 25 as seen from below. FIG. 27 illustrates a state obtained by reversing that illustrated in FIG. 26, and therefore a left end in FIG. 26 is a right end in FIG. 27. In FIG. 27, the state is seen from the second surface 42 side of the ferroelectric layer 1. As illustrated in FIG. 27, a first third electrode 1023, a first fourth electrode 1024, a second third electrode 2023, a second fourth electrode 2024, a third third electrode 3023, a third fourth electrode 3024, . . . , an nth third electrode n023, and an nth fourth electrode n024 are arranged so as to be spaced apart from each other on the first surface 42 of the ferroelectric layer 1. The first third electrode 1023, the second third electrode 2023, . . . , and the nth third electrode n023 may have the same shape as each other. The first fourth electrode 1024, the second fourth electrode 2024, . . . , and the nth fourth electrode n024 may have the same shape as each other.

When arranging the configuration of the piezoelectric device 104 described above, the following features and advantages are noted.

The piezoelectric device 104 of this exemplary embodiment is a piezoelectric device, and includes the ferroelectric layer 1 having the first surface 41 and the second surface 42 that face in opposite directions, where n is an integer greater than or equal to 2. In addition, for each integer k from 1 to n, the piezoelectric device 104 has a kth first electrode that is formed of a sintered metal on the first surface 41, a kth second electrode formed of a sintered metal on the first surface 41, a kth third electrode formed of a sintered metal on the second surface 42, and a kth fourth electrode formed of a sintered metal on the second surface 42, the kth third electrode includes a region that faces the kth first electrode with the ferroelectric layer 1 interposed therebetween, and the kth fourth electrode includes a region that faces at least part of the kth second electrode with the ferroelectric layer 1 interposed therebetween. The first first electrode, the second first electrode, the third first electrode, . . . , the nth first electrode, the first second electrode, the second second electrode, the third second electrode, . . . , and the nth second electrode are spaced apart from each other and arranged in different regions from each other. The first third electrode, the second third electrode, the third third electrode, . . . , the nth third electrode, the first fourth electrode, the second fourth electrode, the third fourth electrode, . . . , and the nth fourth electrode are spaced apart from each other and arranged in different regions from each other. For two different integers k1 and k2 arbitrarily selected from among the integers 1 to n, the k1-th first electrode and the k2-th first electrode have different surface areas from each other.

In this embodiment, n memory parts and n sensor parts are formed inside one piezoelectric device (collectively referred to as a memory and sensor component). A charge is generated in each of the n sensor parts when a single impact acts on the piezoelectric device. Each charge causes a potential difference to be generated between the first electrode and the third electrode in the corresponding memory part. Even in the case where identical charges are generated by the respective sensor parts, since the surface areas of the respective first electrodes are different from each other in n specific memory parts, different voltages are applied to the corresponding memory parts. Due to the fact that the voltages that are applied to the respective memory parts are different from each other, a series circuit in which polarization inversion is possible and a series circuit in which polarization inversion is not possible can exist among a plurality of specific memory parts. The size of an impact that has acted on the piezoelectric device can be quantitatively confirmed by subsequently checking the presence/absence of polarization inversion in each memory part.

In this exemplary aspect, the ferroelectric layer 1 can have thickness of 1 to 100 μm.

As illustrated in this embodiment, for each integer k from 1 to n, the kth first electrode may have a circular shape, and the kth second electrode may be arranged so as to surround the kth first electrode. By adopting this configuration, the surface area of the first electrode may be easily adjusted. In addition, by adopting this configuration, regions of the ferroelectric layer 1 that are not covered by either a kth first electrode or a kth second electrode can be made small. The ferroelectric layer 1 being covered by either electrode simply means that a ceramic having brittleness is covered by a metal having malleability and the mechanical strength of the ferroelectric layer 1 is reinforced in that region, and if the kth second electrode is arranged so as to surround the kth first electrode, the region that is reinforced in this way can be made large, and therefore generated stress can be relaxed, and the risk of the ferroelectric layer 1 breaking while the electrodes are being processed can be reduced.

As illustrated in FIG. 25, for each integer k from 1 to n, the kth first electrode and the kth second electrode may be electrically connected to each other via the diode 31. As a result of adopting this configuration, the alternating current signal generated by each sensor part is rectified by the diode 31 and then applied to the corresponding memory part.

### Embodiment 5

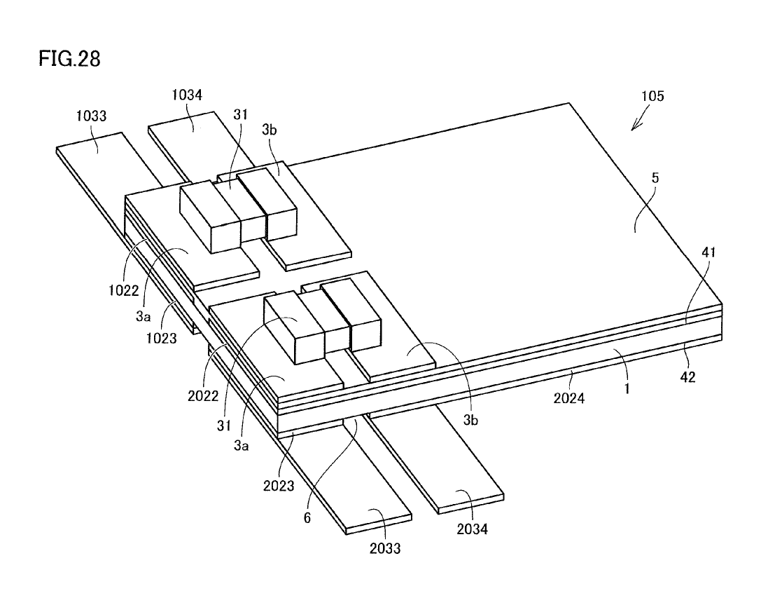

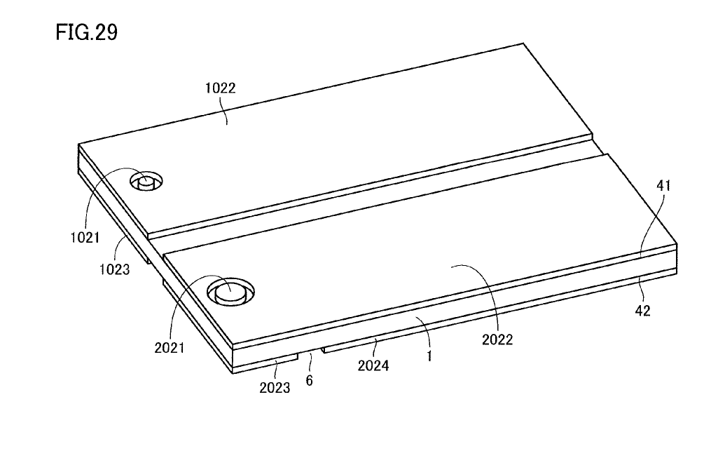

A piezoelectric device of exemplary embodiment 5 of the present disclosure will be described while referring to FIGS. 28 and 29. A piezoelectric device 105 of this embodiment is illustrated in FIG. 28. The piezoelectric device 105 of this embodiment is obtained by making n=2 in the piezoelectric device 104 of embodiment 4, and adding some additional components. FIG. 29 illustrates a state obtained by removing a number of elements such as the insulating film 5 from FIG. 28.

The piezoelectric device 105 of this embodiment is a piezoelectric device, and includes the ferroelectric layer 1 having the first surface 41 and the second surface 42 that face in opposite directions. In addition, the piezoelectric device 105 has a first first electrode 1021 that is formed of a sintered metal on the first surface 41, a first second electrode 1022 formed of a sintered metal on the first surface 41, a first third electrode 1023 formed of a sintered metal on the second surface 42, and a first fourth electrode formed of a sintered metal on the second surface 42, the first third electrode 1023 includes a region that faces the first first electrode 1021 with the ferroelectric layer 1 interposed therebetween, and the first fourth electrode includes a region that faces at least part of the first second electrode 1022 with the ferroelectric layer 1 interposed therebetween. In addition, the piezoelectric device 105 has a second first electrode 2021 that is formed of a sintered metal on the first surface 41, a second second electrode 2022 that is formed of a sintered metal on the first surface 41, a second third electrode 2023 that is formed of a sintered metal on the second surface 42, and a second fourth electrode 2024 that is formed of a sintered metal on the second surface 42. The second third electrode 2023 includes a region that faces the second first electrode 2021 with the ferroelectric layer 1 interposed therebetween. The second fourth electrode 2024 includes a region that faces at least part of the second second electrode 2022 with the ferroelectric layer 1 interposed therebetween. The first first electrode 1021, the second first electrode 2021, the first second electrode 1022, and the second second electrode 2022 are spaced apart from each other and arranged in different regions from each other. The first third electrode 1023, the second third electrode 2023, the first fourth electrode, and the second fourth electrode 2024 are spaced apart from each other and arranged in different regions from each other. The first first electrode 1021 and the second first electrode 2021 have different surface areas from each other.

As illustrated in FIG. 28, a first first pad electrode 1033 is connected to the first third electrode 1023. A first second pad electrode 1034 is connected to the first fourth electrode, which is not illustrated. A second first pad electrode 2033 is connected to the second third electrode 2023. A second second pad electrode 2034 is connected to the second fourth electrode 2024.

In this embodiment, two memory parts and two sensor parts (each considered a memory and sensor component) are formed inside one piezoelectric device 105. In this embodiment, the first first electrode 1021 and the second first electrode 2021 have different surface areas, and therefore the voltages applied to the two memory parts are different from each other when a single impact acts on the piezoelectric device. When an impact acts on the piezoelectric device 105, three states are possible, namely, polarization inversion occurs in both of the two memory parts, polarization inversion occurs in only one memory part, and polarization inversion does not occur in either of the two memory parts, and the relative size of the impact acting on the piezoelectric device 105 can be identified by subsequently analyzing which of these states occurred.

A plurality of the above-described embodiments may be combined with each other as appropriate. In addition, the presently disclosed embodiments are illustrative in all points and are not restrictive. The scope of the present invention is not to be defined by the above description but rather by the scope of the claims, and equivalents to the scope of the claims and all modifications within the scope of the claims are to be included within the scope of the present invention.

### REFERENCE SIGNS LIST

1 ferroelectric layer,
3a, 3b extension electrode,
5 insulating layer,
5a, 5b opening (in insulating film),
6 gap,
10 piezoelectric ceramic sheet,
11 first conductive sheet,
12 second conductive sheet,
15 co-sintered compact
16 first conductor layer,
17 second conductor layer,
21 first electrode,
22 second electrode,
22c opening (in second electrode)
23 third electrode,
24 fourth electrode,
25 wiring line,
31 diode,
32 substrate,
33 first pad electrode,
34 second pad electrode,
35 switch,
41 first surface,
42 second surface,
51 sensor part,
52 memory part,
101, 102, 103, 104, 105 piezoelectric device,
1021 first first electrode,
1022 first second electrode,
1023 first third electrode,
1033 first first pad electrode,
1034 first second pad electrode,
2021 second first electrode,
2022 second second electrode,
2023 second third electrode,
2024 second fourth electrode,
2033 second first pad electrode,
2034 second second pad electrode.

1. A piezoelectric device comprising:
a ferroelectric layer a having a first and second opposing surfaces that face opposite directions;
a first electrode that covers a portion of the first surface of the ferroelectric layer;
a second electrode that is spaced apart from the first electrode and that covers a portion of the first surface of the ferroelectric layer that is not covered by the first electrode;
a third electrode that covers a portion of the second surface of the ferroelectric layer, such that the third electrode covers a region of the second surface that faces a region of the first surface covered by the first electrode; and
a fourth electrode that is spaced apart from the third electrode and that covers a portion of the second surface of the ferroelectric layer that is not covered by the third electrode,
wherein at least a portion of the fourth electrode faces at least a portion of the second electrode with the ferroelectric layer interposed therebetween.

2. The piezoelectric device according to claim 1, wherein each of the first, second, third and fourth electrodes comprise a sintered metal.

3. The piezoelectric device according to claim 1, wherein the ferroelectric layer has a thickness between 1 μm and 100 μm.

4. The piezoelectric device according claim 1, wherein the first electrode comprises a circular shape, and the second electrode is disposed on the first surface of the ferroelectric layer so as to surround the first electrode.

5. The piezoelectric device according claim 1, wherein the first electrode comprises an island shape surrounded by the second electrode.

6. The piezoelectric device according to claim 1, further comprising a diode that electrically connects the first electrode to the second electrode.

7. The piezoelectric device according to claim 1, further comprising:
a first pad electrode electrically connected to the third electrode; and
a second pad electrode electrically connected to the fourth electrode,
wherein the first and second pad electrodes are configured to be switched between being electrically connected to each other and not electrically connected to each other.

8. The piezoelectric device according to claim 1, further comprising an insulating film that covers at least part of the first electrode and at least part of the second electrode.

9. A piezoelectric device comprising:
a ferroelectric layer having first and second opposing surfaces that face opposite directions;
a plurality of n memory and sensor components, wherein n is an integer greater than or equal to 2,
wherein each memory and sensor component k from 1 to n of the n memory and sensor components comprises:
a kth first electrode disposed on the first surface;
a kth second electrode disposed on the first surface;
a kth third electrode disposed on the second surface; and
a kth fourth electrode disposed on the second surface,
wherein the kth third electrode of each of the plurality of n memory and sensor components covers a region of the second surface that faces the kth first electrode with the ferroelectric layer interposed therebetween,
wherein the kth fourth electrode of each of the plurality of n memory and sensor components covers a region that faces at least a portion of the kth second electrode with the ferroelectric layer interposed therebetween,
wherein each kth first electrode of each of the plurality of n memory and sensor components is spaced apart on the first surface from each kth second electrode, respectively,
wherein each kth third electrode of each of the n memory and sensor components is spaced apart on the second surface from each kth fourth electrode, respectively, and
wherein, for two different memory and sensor components k1 and k2 arbitrarily selected from the 1 to n memory and sensor components, the first electrode of the memory and sensor component k1 has a different surface area from the first electrode of the memory and sensor component k2.

10. The piezoelectric device according to claim 9, wherein each of the first, second, third and fourth electrodes of the plurality of n memory and sensor components comprises a sintered metal.

11. The piezoelectric device according to claim 9, wherein the ferroelectric layer has a thickness between 1 μm and 100 μm.

12. The piezoelectric device according to claim 9, wherein for each memory and sensor component k of the plurality of n memory and sensor components, the kth first electrode comprises a circular shape, and the kth second electrode is disposed on the first surface of the ferroelectric layer so as to surround the kth first electrode, respectively.

13. The piezoelectric device according claim 9, wherein for each memory and sensor component k of the plurality of n memory and sensor components, the kth first electrode comprises an island shape surrounded by the kth second electrode.

14. The piezoelectric device according to claim 9, wherein each memory and sensor component k of the plurality of n memory and sensor components comprises a diode that electrically connects the respective kth first electrode to the respective kth second electrode.

15. A piezoelectric device comprising:
a ferroelectric layer a having a first and second opposing surfaces;
a first electrode disposed on a first surface portion of the first surface of the ferroelectric layer;
a second electrode disposed on a second surface portion of the first surface of the ferroelectric layer that is different than the first surface portion of the first surface;
a third electrode disposed on a first surface portion of the second surface of the ferroelectric layer, with the first surface portion of the second surface overlapping at least a portion of the first surface portion of the first surface in a thickness direction of the piezoelectric device; and
a fourth electrode that is spaced apart from the third electrode and that is disposed on a second surface portion of the second surface of the ferroelectric layer that is different than the first surface portion of the second surface,
wherein at least a portion of the fourth electrode overlaps at least a portion of the second electrode in the thickness direction of the piezoelectric device.

16. The piezoelectric device according to claim 15, wherein each of the first, second, third and fourth electrodes comprise a sintered metal.

17. The piezoelectric device according to claim 15, wherein the ferroelectric layer has a thickness between 1 μm and 100 μm.

18. The piezoelectric device according claim 15, wherein the first electrode comprises a circular shape, and the second electrode is disposed on the first surface of the ferroelectric layer so as to surround the first electrode.

19. The piezoelectric device according to claim 15, further comprising a diode that electrically connects the first electrode to the second electrode.

20. The piezoelectric device according to claim 15, further comprising:
a first pad electrode electrically connected to the third electrode; and
a second pad electrode electrically connected to the fourth electrode,
wherein the first and second pad electrodes are configured to be switched between being electrically connected to each other and not electrically connected to each other.
